(19) United States
(12) Patent Application Publication
(10) Pub. No.: US 2024/0312758 A1
(43) Pub. Date: Sep. 19, 2024

(54) SYSTEM AND METHOD FOR ADJUSTING BEAM CURRENT USING A FEEDBACK LOOP IN CHARGED PARTICLE SYSTEMS

(71) Applicants: ASML Netherlands B.V., Veldhoven (NL); HERMES MICROVISION CO. LTD. (BEIJING), Beijing (CN)

(72) Inventors: Zheng FAN, Beijing (CN); Bruno LA FONTAINE, Pleasanton, CA (US); He Sheng LU, Beijing (CN); Gao Xing YIN, Beijing (CN); Shun ZHANG, Beijing (CN); Zhenfeng ZHAO, Fremont, CA (US)

(21) Appl. No.: 18/571,186

(22) PCT Filed: May 30, 2022
(86) PCT No.: PCT/EP2022/064577

§ 371 Date: Dec. 15, 2023

(30) Foreign Application Priority Data
Jun. 18, 2021 (WO) PCT/CN2021/10095

(51) Int. Cl. H01J 37/24; H01J 37/065; H01J 37/28

(52) U.S. Cl. CPC H01J 37/243; H01J 37/065; H01J 37/28; H01J 2237/04735; H01J 2237/24535

(57) ABSTRACT

Apparatuses, systems, and methods for adjusting beam current using a feedback loop are provided. In some embodiments, a system may include a first anode aperture configured to measure a current of an emitted beam during inspection of a sample, wherein the first anode aperture is positioned in an environment that is configured to support a vacuum pressure of less than 3×10⁻¹⁰ torr and a controller including circuitry configured to cause the system to perform: generating a feedback signal when a difference between the measured current and a setpoint current exceeds a threshold value and adjusting a voltage of an extractor voltage supply based on the feedback signal during inspection of the sample such that a difference between an adjusted current of the emitted beam and the setpoint current is below the threshold value.

### CROSS-REFERENCE TO RELATED APPLICATIONS

This application claims priority of WO application PCT/CN2021/100955 which was filed on 18 Jun. 2021 and which is incorporated herein in its entirety by reference.

### FIELD

The description herein relates to the field of charged particle beam systems, and more particularly to systems for adjusting beam current using a feedback loop in charged particle beam system inspection systems.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused at locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for adjusting beam current using a feedback loop in charged particle beam system inspection systems. In some embodiments, a system may include a first anode aperture configured to measure a current of an emitted beam during inspection of a sample, wherein the first anode aperture is positioned in an environment that is configured to support a vacuum pressure of less than 3×10⁻¹⁰ torr and a controller including circuitry configured to cause the system to perform: generating a feedback signal when a difference between the measured current and a setpoint current exceeds a threshold value and adjusting a voltage of an extractor voltage supply based on the feedback signal during inspection of the sample such that a difference between an adjusted current of the emitted beam and the setpoint current is below the threshold value.

In some embodiments, a method for adjusting beam current using a feedback loop in charged particle beam system inspection systems may include measuring, by a first anode aperture in an environment that is configured to support a vacuum pressure of less than 3×10⁻¹⁰ torr, a current of an emitted beam during inspection of a sample; generating, by a controller, a feedback signal when a difference between the measured current and a setpoint current exceeds a threshold value; and adjusting a voltage of an extractor voltage supply based on the feedback signal during inspection of the sample such that a difference between an adjusted current of the emitted beam and the setpoint current is below the threshold value.

In some embodiments, a non-transitory computer readable medium may store a set of instructions that is executable by at least one processor of a computing device to cause the computing device to perform a method for adjusting beam current using a feedback loop in charged particle beam system inspection systems. The method may include acquiring a measured current of an emitted beam during inspection of a sample, wherein the measured current is measured by a first anode aperture in an environment that is configured to support a vacuum pressure of less than 3×10⁻¹⁰ torr; generating a feedback signal when a difference between the measured current and a setpoint current exceeds a threshold value; and adjusting a voltage of an extractor voltage supply based on the feedback signal during inspection of the sample such that a difference between an adjusted current of the emitted beam and the setpoint current is below the threshold value.

### BRIEF DESCRIPTION OF THE DRAWINGS

FIG. 1 is a schematic diagram illustrating an exemplary electron beam inspection (EBI) system, consistent with embodiments of the present disclosure.

FIG. 2 is a schematic diagram illustrating an exemplary electron beam tool that is part of the exemplary charged particle beam inspection system of FIG. 1, consistent with embodiments of the present disclosure.

FIG. 3 is a schematic diagram illustrating an exemplary electron beam tool that is part of the exemplary charged particle beam inspection system of FIG. 1, consistent with embodiments of the present disclosure.

FIG. 4 is a schematic diagram illustrating an exemplary feedback loop for adjusting beam current, consistent with embodiments of the present disclosure.

FIG. 5 is a flowchart illustrating an exemplary process for adjusting beam current using a feedback loop, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

During some inspections (e.g., using a high brightness source, thermal field emitters with very fine tips, operating at high extraction electric fields, reduced operating temperatures such as less than 1750K or less than 1700K, etc.), the current of an emitted beam may vary, thereby damaging the sample or negatively affecting the SEM images (e.g., inaccurate or varying gray scale levels across images, low critical dimension stability, poor image quality, etc.).

Typical charged particle systems may measure the beam current at the extractor aperture, the moving aperture, the gate valve, the column aperture, the retractable Faraday cup, the lower gun chamber, or at the main chamber. Additionally, typical charged particle systems emit electrons freely in an open loop (e.g., without generating feedback signals) once system parameters are set. However, typical charged particle systems suffer from constraints. For example, measuring the beam current at these parts of a system or once the system parameters are set may require changing the parts or structure of the e-beam column in order to correct the beam current. Moreover, measuring the beam current at these parts may not be possible in real-time. Therefore, typical charged particle systems are unable to monitor beam current in real-time and unable to correct the beam current when it fluctuates during inspection.

Some of the disclosed embodiments provide systems and methods that address some or all of these disadvantages by adjusting beam current using a feedback loop. The disclosed embodiments may provide systems and methods that measure the current of an emitted beam using an anode aperture in real-time during inspection of a sample and adjust a voltage of the extractor voltage supply using a current feedback loop. The disclosed embodiments may use a feedback loop to maintain the stability of the beam current in real-time during inspection by monitoring changes in the beam current in real-time and automatically changing the extractor voltage using the feedback loop, thereby advantageously providing high quality samples and images (e.g., by maintaining critical dimension stability, uniform and stable gray levels in images, repeatability in samples and images, etc.) over long periods of time (e.g., for at least several months).

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

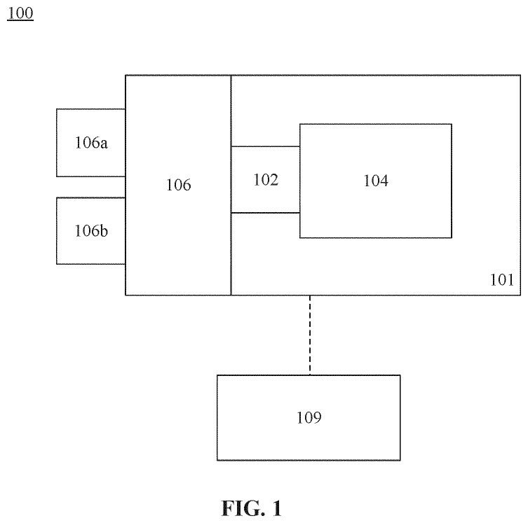

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

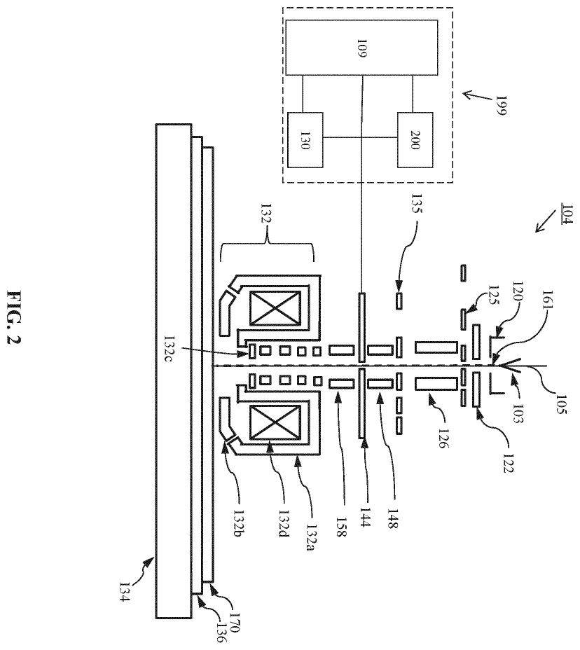

Reference is now made to FIG. 2, which is a schematic diagram illustrating an exemplary electron beam tool 104 that is part of the EBI system 100 of FIG. 1, consistent with embodiments of the present disclosure.

A detector may be placed along an optical axis 105, as shown in FIG. 2. In some embodiments, a detector may be arranged off axis.

As shown in FIG. 2, an electron beam tool 104 may include a holder 136 supported by motorized stage 134 to hold a sample 170 to be inspected. Electron beam tool 104 may be a single-beam system or a multi-beam system. Electron beam tool 104 includes an electron beam source, which may comprise a cathode 103, an anode 120, and a gun aperture 122. Electron beam tool 104 further includes a beam limit aperture 125, a condenser lens 126, a column aperture 135, an objective lens assembly 132, and an electron detector 144. Objective lens assembly 132, in some embodiments, may be a modified swing objective retarding immersion lens (SORIL), which includes a pole piece 132a, a control electrode 132b, a deflector 132c, and an exciting coil 132d. In an imaging process, an electron beam 161 emanating from the tip of cathode 103 may be accelerated by anode 120 voltage, pass through gun aperture 122, beam limit aperture 125, condenser lens 126, and focused into a probe spot by the modified SORIL lens and then impinge onto the surface of sample 170. The probe spot may be scanned across sample 170 by a deflector, such as deflector 132c or other deflectors in the SORIL lens. Secondary electrons emanated from sample 170 may be collected by detector 144 to form an image of an area of interest on sample 170.

There may also be provided an image processing system 199 that includes an image acquirer 200, a storage 130, and a controller 109. Image acquirer 200 may comprise one or more processors. For example, image acquirer 200 may comprise a computer, server, mainframe host, terminals, personal computer, any kind of mobile computing devices, and the like, or a combination thereof. Image acquirer 200 may connect with detector 144 of electron beam tool 104 through a medium such as an electrical conductor, optical fiber cable, portable storage media, IR, Bluetooth, internet, wireless network, wireless radio, or a combination thereof. Image acquirer 200 may receive a signal from detector 144 and may construct an image. Image acquirer 200 may thus acquire images of sample 170. Image acquirer 200 may also perform various post-processing functions, such as generating contours, superimposing indicators on an acquired image, and the like. Image acquirer 200 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 200 and may be used for saving scanned raw image data as original images, and post-processed images. Image acquirer 200 and storage 130 may be connected to controller 109. Controller 109 may be electronically connected to electron beam tool 104. Controller 109 may be a computer configured to execute various controls of electron beam tool 104. In some embodiments, image acquirer 200, storage 130, and controller 109 may be integrated together as one control unit.

In some embodiments, image acquirer 200 may acquire one or more images of a sample based on an imaging signal received from detector 144. An imaging signal may correspond to a scanning operation for conducting charged particle imaging. An acquired image may be a single image comprising a plurality of imaging areas that may contain various features of sample 170. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2, the electron beam tool 104 may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape. It is to be appreciated that any number of poles and any number of lenses may be used, as appropriate.

Although FIG. 2 shows electron beam tool 104 as a single-beam inspection tool that may use only one primary electron beam to scan one location of sample 170 at a time, embodiments of the present disclosure are not so limited. For example, electron beam tool 104 may also be a multi-beam inspection tool that employs multiple primary electron beamlets to simultaneously scan multiple locations on sample 170.

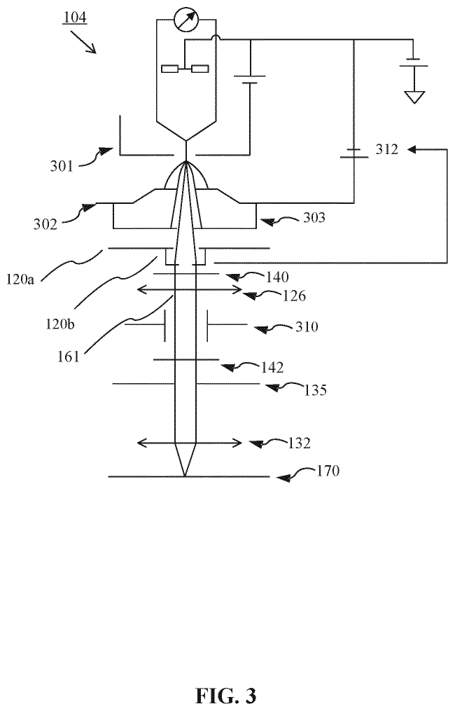

FIG. 3 illustrates a schematic diagram illustrating an exemplary electron beam tool that is part of the exemplary charged particle beam inspection system of FIG. 1, consistent with embodiments of the present disclosure. The components of FIG. 3 are similar to those of FIG. 2, except that FIG. 3 provides components for describing a feedback loop.

Electron beam tool 104 may include an electron source 301 (e.g., Schottky-type) and an extractor 302 in which, during operation, electron source 301 is configured to emit primary electrons 161 from the cathode (e.g., cathode 103 of FIG. 2) and the primary electrons may be extracted or accelerated by extractor 302 and extractor aperture 303 to form primary electron beam 161. Electron beam tool 104 may include an extractor voltage supply 312 that may be used to form primary electron beam 161 with a set current. Anode 120 may comprise a first anode aperture 120a and a second anode aperture 120b, where electron beam 161 emanating from the tip of cathode 103 may be accelerated by a voltage of first anode aperture 120a. In some embodiments, an aberration compensator array may comprise a field curvature compensator array (not shown) and an astigmatism compensator array 310. The field curvature compensator array may comprise a plurality of micro-lenses to compensate field curvature aberrations of primary electron beam 161. Astigmatism compensator array 310 may comprise a plurality of micro-stigmators to compensate astigmatism aberrations of primary electron beam 161. Electron beam tool 104 may include a moving aperture 140 and a gate valve 142.

While certain elements may be named “first” or “second,” the naming convention of these elements is not limited to this naming convention.

In some embodiments, electron beam tool 104 may include a controller (e.g., controller 109 of FIG. 2) that includes circuitry configured to cause a system (e.g., EBI system 100 of FIG. 1) to perform measuring a current of emitted electron beam 161 using second anode aperture 120b in real-time during inspection of sample 170. In some embodiments, second anode aperture 120b may be configured to measure emitted electron beam 161 without perturbing electron beam 161. In some embodiments, second anode aperture 120b may be configured to measure a portion of emitted electron beam 161. In some embodiments, first anode aperture 120a and second anode aperture 120b may be isolated from other components of the system.

In some embodiments, the controller (e.g., controller 109 of FIG. 2) may be a proportional-integral-derivative (PID) controller. For example, the PID controller may continuously, in real-time during inspection, calculate an error value as the difference between a setpoint current and the current of electron beam 161 measured by second anode aperture 120b. When the error value exceeds a threshold value (e.g., a greater than 1% difference between the setpoint current and the measured current of electron beam 161), the PID controller may generate a feedback signal and transmit the feedback signal to extractor voltage supply 312. Based on the feedback signal, the PID controller may adjust a voltage of extractor voltage supply 312 such that electron source 301 emits primary electron beam 161 with an adjusted current.

In some embodiments, the PID controller may adjust the voltage of extractor voltage supply 312 in real-time during inspection such that an error value between the setpoint current and the adjusted current of electron beam 161 is within the threshold value (e.g., less than or equal to 1% difference between the setpoint current and the measured current of electron beam 161). In some embodiments, the PID controller may continuously calculate an error value between the setpoint current and the current of electron beam 161 measured by second anode aperture 120b in real-time during inspection in order to automatically apply accurate corrections to the current of electron beam 161 by adjusting the voltage of extractor voltage supply 312 (e.g., by adjusting a voltage of extractor voltage supply 312 such that the current of electron beam 161 is adjusted by a value equal to the difference between the current of electron beam 161 and the setpoint current). In some embodiments, when the error value is within the threshold value, the PID controller may not generate a feedback signal and the voltage of extractor voltage supply 312 may not be adjusted.

In some embodiments, second anode aperture 120b may include a plurality of segments where each segment of the plurality of segments is insulated from each other. Each segment of the plurality of segments may be configured to measure a current of emitted electron beam 161 in real-time during inspection of sample 170. In some embodiments, each segment of the plurality of segments may be configured to measure a current of a portion of emitted electron beam 161 in real-time during inspection of sample 170. In some embodiments, the PID controller may determine an error (e.g., an emitter pointing error, an angular beam emission distribution error, etc.) based on a measured current of electron beam 161 measured on each segment of the plurality of segments. In some embodiments, the controller may adjust the voltage of extractor voltage supply 312 such that a temperature of a tip of an emitter is adjusted (e.g., by applying cycles of heating the tip of the emitter) in order to correct the error. In some embodiments, the controller may adjust the voltage of extractor voltage supply 312 such that an electric field of extractor 302 is adjusted (e.g., by applying ramps of electric fields) in order to correct the error.

In some embodiments, second anode aperture 120b may be positioned in a vacuum chamber. In some embodiments, the vacuum chamber may operate at a high vacuum (e.g., a pressure of less than 3×10⁻¹⁰ torr), and in other embodiments the vacuum chamber may operate at an ultra-high vacuum (e.g., a pressure of less than 1×10⁻¹⁰ torr). For clarity, a pressure of 1×10⁻¹⁰ torr is less than a pressure of 3×10⁻¹⁰ torr. For example, in some embodiments, a longer electron source life can be achieved by operating a vacuum chamber at an ultra-high vacuum (e.g., by emitting a beam from the electron source with a more stable current), but with the trade-off of a higher system cost due to the costs of achieving an ultra-high vacuum. In some embodiments, a lower cost system can be achieved by operating a vacuum chamber at a high vacuum, but with the trade-off of that the lower pressure may result in a shorter electron source life than operating at an ultra-high vacuum.

In some embodiments, the controller may adjust a focus of electron beam 161 in response to an adjusted voltage of extractor voltage supply 312 (e.g., the focus of electron beam 161 may change as a result of the adjusted voltage of extractor voltage supply 312 and the focus of electron beam 161 may need to be adjusted or corrected as a result).

In some embodiments a controller (e.g., controller 109 of FIG. 2) may include circuitry configured to cause a system (e.g., EBI system 100 of FIG. 1) to perform measuring a current of electron beam 161 using second anode aperture 120b in real-time during inspection of sample 170. In some embodiments, second anode aperture 120b may be configured to measure a current of a portion of emitted electron beam 161 in real-time during inspection of sample 170. In some embodiments, second anode aperture 120b may be configured to measure emitted electron beam 161 without perturbing electron beam 161. In some embodiments, first anode aperture 120a and second anode aperture 120b may be isolated from other components of the system. In some embodiments, the controller may not sue a feedback loop during measurement of the current of electron beam 161.

In some embodiments, a controller (e.g., controller 109 of FIG. 2) may determine an error (e.g., an emitter pointing error, an angular beam emission distribution error, etc.) based on a measured current of electron beam 161 measured on each segment of the plurality of segments without used a feedback loop. In some embodiments, the controller may adjust a parameter of the system based on the error. For example, when the measured current exceeds a threshold value, the measured current may indicate that an error of electric discharge exists in the system. In some embodiments, the adjusted parameter of the system may be a voltage of extractor voltage supply 312, which may be adjusted by the controller in order to correct the error.

In some embodiments, second anode aperture 120b may include a plurality of segments where each segment of the plurality of segments is insulated from each other. Each segment of the plurality of segments may be configured to measure a current of emitted electron beam 161 in real-time during inspection of sample 170 without using a feedback loop. In some embodiments, the PID controller may determine an error (e.g., an emitter pointing error, an angular beam emission distribution error, etc.) based on a measured current of electron beam 161 measured on each segment of the plurality of segments. In some embodiments, each segment of the plurality of segments may be configured to measure a current of a portion of emitted electron beam 161 in real-time during inspection of sample 170.

In some embodiments, the controller may adjust the voltage of extractor voltage supply 312 such that a temperature of a tip of an emitter is adjusted (e.g., by applying cycles of heating the tip of the emitter) in order to correct the error. In some embodiments, the controller may adjust the voltage of extractor voltage supply 312 such that an electric field of extractor 302 is adjusted (e.g., by applying ramps of electric fields) in order to correct the error. In some embodiments, the adjusted parameter may be a distance between a tip of the emitter and extractor 302, which may be adjusted to correct the error.

In some embodiments, second anode aperture 120b may be positioned in a vacuum chamber. In some embodiments, the vacuum chamber may operate at a high vacuum (e.g., a pressure of less than 3×10⁻¹⁰ torr), and in other embodiments the vacuum chamber may operate at an ultra-high vacuum (e.g., a pressure of less than 1×10⁻¹⁰ torr). For example, in some embodiments, a longer electron source life can be achieved by operating a vacuum chamber at an ultra-high vacuum (e.g., by emitting a beam from the electron source with a more stable current), but with the trade-off of a higher system cost due to the costs of achieving an ultra-high vacuum. In some embodiments, a lower cost system can be achieved by operating a vacuum chamber at a high vacuum, but with the trade-off of that the lower pressure may result in a shorter electron source life than operating at an ultra-high vacuum. In some embodiments, the adjusted parameter may be a condition of the vacuum chamber (e.g., a pressure of the vacuum chamber), which may be adjusted to correct the error.

In some embodiments, the controller may adjust a focus of electron beam 161 in response to an adjusted voltage of extractor voltage supply 312 (e.g., the focus of electron beam 161 may change as a result of the adjusted voltage of extractor voltage supply 312 and the focus of electron beam 161 may need to be adjusted or corrected as a result).

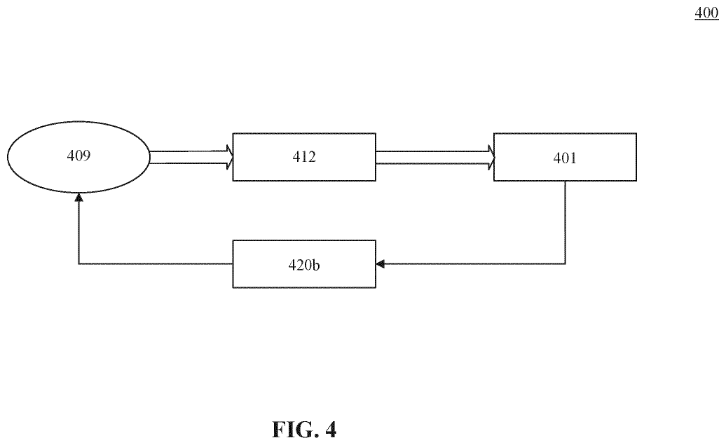

FIG. 4 illustrates a schematic diagram illustrating an exemplary feedback loop 400 for adjusting beam current, consistent with embodiments of the present disclosure.

In some embodiments, an electron beam tool (e.g., electron beam tool 104 of FIG. 2 or FIG. 3) may include a controller 409 (e.g., controller 109 of FIG. 2 or FIG. 3) that includes circuitry configured to cause a system (e.g., EBI system 100 of FIG. 1) to perform measuring a current of an emitted electron beam (e.g., emitted electron beam 161 of FIG. 2 or FIG. 3) using second anode aperture 420b (e.g., second anode aperture 120b of FIG. 3) in real-time during inspection of a sample (e.g., sample 170 of FIG. 2 or FIG. 3). In some embodiments, second anode aperture 420b may be configured to measure the emitted electron beam without perturbing the electron beam. In some embodiments, second anode aperture 420b may be configured to measure a current of a portion of emitted electron beam 161 in real-time during inspection of a sample. In some embodiments, a first anode aperture (e.g., first anode aperture 120a of FIG. 3) and second anode aperture 420b may be isolated from other components of the system.

In some embodiments, controller 409 may be a PID controller. For example, the PID controller may continuously, in real-time during inspection, calculate an error value as the difference between a setpoint current and the current of the electron beam measured by second anode aperture 420b. When the error value exceeds a threshold value (e.g., a greater than 1% difference between the setpoint current and the measured current of electron beam 161), the PID controller may generate a feedback signal and transmit the feedback signal to extractor voltage supply 412 (e.g., extractor voltage supply 312 of FIG. 3). Based on the feedback signal, the PID controller may adjust a voltage of extractor voltage supply 412 such that an electron source 401 (e.g., electron source 301 of FIG. 3) emits a primary electron beam with an adjusted current.

In some embodiments, the PID controller may adjust the voltage of extractor voltage supply 412 in real-time during inspection such that an error value between the setpoint current and the adjusted current of the electron beam is within the threshold value (e.g., less than or equal to 1% difference between the setpoint current and the measured current of electron beam 161 of FIG. 2 or FIG. 3). In some embodiments, the PID controller may continuously calculate an error value between the setpoint current and the current of the electron beam measured by second anode aperture 420b in real-time during inspection in order to automatically apply accurate corrections to the current of the electron beam by adjusting the voltage of extractor voltage supply 412 (e.g., by adjusting a voltage of extractor voltage supply 412 such that the current of electron beam 161 is adjusted by a value equal to the difference between the current of electron beam 161 and the setpoint current). In some embodiments, when the error value is within the threshold value, the PID controller may not generate a feedback signal and the voltage of extractor voltage supply 412 may not be adjusted.

In some embodiments, second anode aperture 420b may include a plurality of segments where each segment of the plurality of segments is insulated from each other. Each segment of the plurality of segments may be configured to measure a current of the emitted electron beam in real-time during inspection of a sample. In some embodiments, the PID controller may determine an error (e.g., an emitter pointing error, an angular beam emission distribution error, etc.) based on a measured current of the electron beam measured on each segment of the plurality of segments. In some embodiments, each segment of the plurality of segments may be configured to measure a current of a portion of an emitted electron beam in real-time during inspection of a sample. In some embodiments, the controller may adjust the voltage of extractor voltage supply 412 such that a temperature of a tip of an emitter is adjusted (e.g., by applying cycles of heating the tip of the emitter) in order to correct the error. In some embodiments, the controller may adjust the voltage of extractor voltage supply 412 such that an electric field of an extractor (e.g., extractor 302 of FIG. 3) is adjusted (e.g., by applying ramps of electric fields) in order to correct the error.

In some embodiments, second anode aperture 420b may be positioned in a vacuum chamber. In some embodiments, the vacuum chamber may operate at a high vacuum (e.g., a pressure of less than 3×10⁻¹⁰ torr), and in other embodiments the vacuum chamber may operate at an ultra-high vacuum (e.g., a pressure of less than 1×10⁻¹⁰ torr). For example, in some embodiments, a longer electron source life can be achieved by operating a vacuum chamber at an ultra-high vacuum (e.g., by emitting a beam from the electron source with a more stable current), but with the trade-off of a higher system cost due to the costs of achieving an ultra-high vacuum. In some embodiments, a lower cost system can be achieved by operating a vacuum chamber at a high vacuum, but with the trade-off of that the lower pressure may result in a shorter electron source life than operating at an ultra-high vacuum.

In some embodiments, the controller may adjust a focus of the electron beam in response to an adjusted voltage of extractor voltage supply 412 (e.g., the focus of electron beam 161 may change as a result of the adjusted voltage of extractor voltage supply 412 and the focus of electron beam 161 may need to be adjusted or corrected as a result).

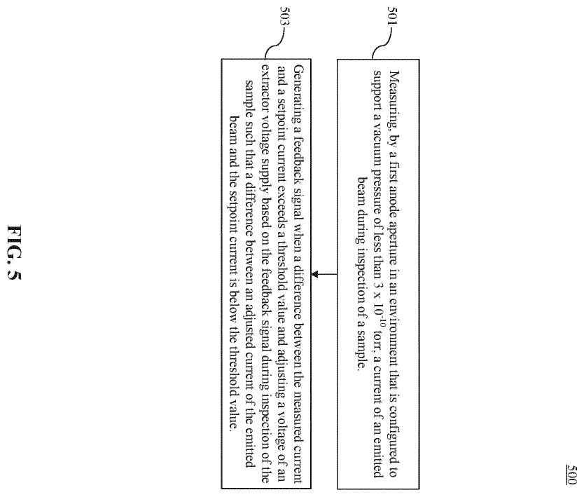

Reference is now made to FIG. 5, a flowchart illustrating an exemplary process 500 for adjusting beam current using a feedback loop, consistent with embodiments of the present disclosure. The steps of method 500 can be performed by a system (e.g., EBI system 100 of FIG. 1) executing on or otherwise using the features of a computing device (e.g., controller 109 of FIG. 1, controller 109 of FIG. 2, controller 409 of FIG. 4, or any components thereof) for purposes of illustration. It is appreciated that the illustrated method 500 can be altered to modify the order of steps and to include additional steps that may be performed by the system.

At step 501, a controller may include circuitry configured to cause a system to perform measuring, by a first anode aperture (e.g., second anode aperture 120b of FIG. 3 or second anode aperture 420b of FIG. 4) in an environment that is configured to support a vacuum pressure of less than 3×10⁻¹⁰ torr, a current of an emitted electron beam (e.g., emitted electron beam 161 of FIG. 2 or FIG. 3) in real-time during inspection of a sample (e.g., sample 170 of FIG. 2 or FIG. 3). In some embodiments, the first anode aperture may be configured to measure the emitted electron beam without perturbing the electron beam. In some embodiments, the first anode aperture may be configured to measure a current of a portion of the emitted electron beam in real-time during inspection of the sample. In some embodiments, a second anode aperture (e.g., first anode aperture 120a of FIG. 3) and the first anode aperture may be isolated from other components of the system.

In some embodiments, the controller may be a PID controller. For example, the PID controller may continuously, in real-time during inspection, calculate an error value as the difference between a setpoint current and the current of the electron beam measured by the first anode aperture.

In some embodiments, the second anode aperture may include a plurality of segments where each segment of the plurality of segments is insulated from each other. Each segment of the plurality of segments may be configured to measure a current of the emitted electron beam in real-time during inspection of the sample. In some embodiments, each segment of the plurality of segments may be configured to measure a current of a portion of the emitted electron beam in real-time during inspection of the sample. In some embodiments, the PID controller may determine an error (e.g., an emitter pointing error, an angular beam emission distribution error, etc.) based on a measured current of the electron beam measured on each segment of the plurality of segments.

In some embodiments, the first anode aperture may be positioned in a vacuum chamber. In some embodiments, the vacuum chamber may operate at a high vacuum (e.g., a pressure of less than 3×10⁻¹⁰ torr), and in other embodiments the vacuum chamber may operate at an ultra-high vacuum (e.g., a pressure of less than 1×10⁻¹⁰ torr.

At step 503, the PID controller may generate a feedback signal when a difference between the measured current and a setpoint current exceeds a threshold value and based on the feedback signal, the PID controller may adjust a voltage of the extractor voltage supply during inspection of the sample such that a difference between an adjusted current of the emitted beam and a setpoint current is below a threshold. For example, when an error value exceeds a threshold value (e.g., a greater than 1% difference between the setpoint current and the measured current of the electron beam), the PID controller may generate a feedback signal and transmit the feedback signal to an extractor voltage supply (e.g., extractor voltage supply 312 of FIG. 3 or extractor voltage supply 412 of FIG. 4). In some embodiments, when the error value is within the threshold value, the PID controller may not generate a feedback signal and the voltage of the extractor voltage supply may not be adjusted. An electron source (e.g., electron source 301 of FIG. 3 or electron source 401 of FIG. 4) may emit a primary electron beam with an adjusted current.

In some embodiments, the PID controller may adjust the voltage of the extractor voltage supply in real-time during inspection such that an error value between the setpoint current and the adjusted current of the electron beam is within the threshold value (e.g., less than or equal to 1% difference between the setpoint current and the measured current of the electron beam). In some embodiments, the PID controller may continuously calculate an error value between the setpoint current and the current of the electron beam measured by the first anode aperture in real-time during inspection in order to automatically apply accurate corrections to the current of the electron beam by adjusting the voltage of extractor voltage supply (e.g., by adjusting a voltage of the extractor voltage supply such that the current of the electron beam is adjusted by a value equal to the difference between the current of the electron beam and the setpoint current).

In some embodiments, the controller may adjust the voltage of the extractor voltage supply such that a temperature of a tip of an emitter is adjusted (e.g., by applying cycles of heating the tip of the emitter) in order to correct an error. In some embodiments, the controller may adjust the voltage of the extractor voltage supply such that an electric field of an extractor (e.g., extractor 302 of FIG. 3) is adjusted (e.g., by applying ramps of electric fields) in order to correct the error.

In some embodiments, the controller may adjust a focus of the electron beam in response to an adjusted voltage of the extractor voltage supply (e.g., the focus of the electron beam may change as a result of the adjusted voltage of the extractor voltage supply and the focus of the electron beam may need to be adjusted or corrected as a result).

A non-transitory computer readable medium may be provided that stores instructions for a processor of a controller (e.g., controller 109 of FIG. 1, controller 109 of FIG. 2, or controller 409 of FIG. 4) for controlling the electron beam tool, or components thereof, consistent with embodiments in the present disclosure. These instructions may allow the one or more processors to carry out beam current adjustment using a feedback loop, image processing, data processing, beamlet scanning, database management, graphical display, operations of a charged particle beam apparatus, or another imaging device, or the like. In some embodiments, the non-transitory computer readable medium may be provided that stores instructions for a processor to perform the steps of process 500. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:

1. An electron beam system comprising:
a first anode aperture configured to measure a current of an emitted beam during inspection of a sample, wherein the first anode aperture is positioned in an environment that is configured to support a vacuum pressure of less than 3×10⁻¹⁰ torr; and
a controller including circuitry configured to cause the system to perform:
generating a feedback signal when a difference between the measured current and a setpoint current exceeds a threshold value; and
adjusting a voltage of an extractor voltage supply based on the feedback signal during inspection of the sample such that a difference between an adjusted current of the emitted beam and the setpoint current is below the threshold value.

2. The system of clause 1, wherein the first anode aperture is configured to measure the emitted beam without perturbing the beam.

3. The system of any one of clauses 1-2, wherein the feedback signal is generated using a proportional-integral-derivative (PID) controller.

4. The system of any one of clauses 1-3, further comprising a second anode aperture configured to accelerate the emitted beam.

5. The system of clause 4, wherein the first anode aperture and the second anode aperture are configured to be isolated from other components of the system.

6. The system of any one of clauses 1-5, wherein the first anode aperture comprises a plurality of segments and each segment of the plurality of segments is insulated from each other.

7. The system of clause 6, wherein each segment of the plurality of segments is configured to measure a current of the emitted beam in during inspection of the sample.

8. The system of clause 7, wherein the circuitry is further configured to cause the system to determine an error based on the current of the emitted beam measured on each segment of the plurality of segments.

9. The system of clause 8, wherein the error comprises an emitter pointing error.

10. The system of clause 8, wherein the error comprises an angular beam emission distribution error.

11. The system of any one of clauses 1-10, wherein the voltage of the extractor voltage supply is adjusted such that a temperature of a tip of an emitter is adjusted.

12. The system of any one of clauses 1-11, wherein the voltage of the extractor voltage supply is adjusted such that an electric field of the extractor is adjusted.

13. The system of any one of clauses 1-12, wherein adjusting the voltage of the extractor voltage supply comprises transmitting the feedback signal to the extractor voltage supply.

14. The system of any one of clauses 1-13, further comprising adjusting a focus of the emitted beam in response to the adjusted voltage of the extractor voltage supply.

15. An electron beam system, the system comprising:
an anode aperture configured to measure a current of an emitted beam during inspection of a sample, wherein the anode aperture is positioned in an environment configured to support a vacuum pressure of less than 3×10⁻¹⁰ torr and wherein the measured current is used to generate a feedback signal when a difference between the measured current and a setpoint current exceeds a threshold value; and
an extractor voltage supply configured to adjust a voltage based on the feedback signal during inspection of the sample such that a difference between an adjusted current of the emitted beam that contacts the anode aperture and a setpoint current is below the threshold value.

16. An electron beam system, the system comprising:
a first anode aperture configured to measure a current of an emitted beam during inspection of a sample; and
a controller including circuitry configured to cause the system to perform:
determining an error based on the measured current; and
adjusting a parameter of the system based on the error.

17. The system of clause 16, wherein the measured current exceeds a threshold value and the error is electric discharge.

18. The system of any one of clauses 16-17, wherein adjusted parameter comprises a voltage of an extractor voltage supply.

19. The system of any one of clauses 16-18, wherein the first anode aperture comprises a plurality of segments and each segment of the plurality of segments is insulated from each other.

20. The system of clause 19, wherein each segment of the plurality of segments is configured to measure a current of the emitted beam during inspection of the sample.

21. The system of clause 20, wherein the circuitry is further configured to cause the system to determine the error based on the current of the emitted beam measured on each segment of the plurality of segments.

22. The system of any one of clauses 16-21, wherein the error comprises an emitter pointing error.

23. The system of any one of clauses 16-21, wherein the error comprises an angular beam emission distribution error.

24. The system of any one of clauses 16-23, wherein the voltage of the extractor voltage supply is adjusted such that a temperature of a tip of an emitter is adjusted.

25. The system of any one of clauses 16-24, wherein the voltage of the extractor voltage supply is adjusted such that an electric field of the extractor is adjusted.

26. The system of any one of clauses 16-25, wherein the adjusted parameter comprises a distance between a tip of the emitter and an extractor.

27. The system of any one of clauses 16-26, wherein the adjusted parameter comprises a condition of the environment in which the first anode aperture is positioned.

28. A method comprising:
measuring, by a first anode aperture in an environment that is configured to support a vacuum pressure of less than 3×10⁻¹⁰ torr, a current of an emitted beam during inspection of a sample;
generating a feedback signal when a difference between the measured current and a setpoint current exceeds a threshold value; and
adjusting a voltage of an extractor voltage supply based on the feedback signal during inspection of the sample such that a difference between an adjusted current of the emitted beam and the setpoint current is below the threshold value.

29. The method of clause 28, wherein the first anode aperture is configured to measure the emitted beam without perturbing the beam.

30. The method of any one of clauses 28-29, wherein the feedback signal is generated using a proportional-integral-derivative (PID) controller.

31. The method of any one of clauses 28-30, wherein the first anode aperture and a second anode aperture are configured to be isolated from other components of a system, wherein the second anode aperture is configured to accelerate the emitted beam.

32. The method of any one of clauses 28-31, wherein the first anode aperture comprises a plurality of segments and each segment of the plurality of segments is insulated from each other.

33. The method of clause 32, wherein each segment of the plurality of segments is configured to measure a current of the emitted beam during inspection of the sample.

34. The method of clause 33, further comprising determining an error based on the current of the emitted beam measured on each segment of the plurality of segments.

35. The method of clause 34, wherein the error comprises an emitter pointing error.

36. The method of clause 34, wherein the error comprises an angular beam emission distribution error.

37. The method of any one of clauses 28-36, wherein the voltage of the extractor voltage supply is adjusted such that a temperature of a tip of an emitter is adjusted.

38. The method of any one of clauses 28-37, wherein the voltage of the extractor voltage supply is adjusted such that an electric field of the extractor is adjusted.

39. The method of any one of clauses 28-38, wherein adjusting the voltage of the extractor voltage supply comprises transmitting the feedback signal to the extractor voltage supply.

40. The method of any one of clauses 28-39, further comprising adjusting a focus of the emitted beam in response to the adjusted voltage of the extractor voltage supply.

41. A non-transitory computer readable medium that stores a set of instructions that is executable by at least one processor of a computing device to cause the computing device to perform a method comprising:
acquiring a measured current of an emitted beam during inspection of a sample, wherein the measured current is measured by a first anode aperture in an environment that is configured to support a vacuum pressure of less than 3×10⁻¹⁰ torr;
generating a feedback signal when a difference between the measured current and a setpoint current exceeds a threshold value; and
adjusting a voltage of an extractor voltage supply based on the feedback signal during inspection of the sample such that a difference between an adjusted current of the emitted beam and the setpoint current is below the threshold value.

42. The non-transitory computer readable medium of clause 41, wherein the first anode aperture is configured to measure the emitted beam without perturbing the beam.

43. The non-transitory computer readable medium of any one of clauses 41-42, wherein the feedback signal is generated using a proportional-integral-derivative (PID) controller.

44 The non-transitory computer readable medium of any one of clauses 41-43, wherein the first anode aperture and a second anode aperture are configured to be isolated from other components of a system, wherein the second anode aperture is configured to accelerate the emitted beam.

45. The non-transitory computer readable medium of any one of clauses 41-44, wherein the first anode aperture comprises a plurality of segments and each segment of the plurality of segments is insulated from each other.

46. The non-transitory computer readable medium of clause 45, wherein each segment of the plurality of segments is configured to measure a current of the emitted beam during inspection of the sample.

47. The non-transitory computer readable medium of clause 46, wherein the set of instructions that is executable by the at least one processor of the computing device to cause the computing device to further perform determining an error based on the current of the emitted beam measured on each segment of the plurality of segments.

48. The non-transitory computer readable medium of clause 47, wherein the error comprises an emitter pointing error.

49. The non-transitory computer readable medium of clause 47, wherein the error comprises an angular beam emission distribution error.

50. The non-transitory computer readable medium of any one of clauses 41-49, wherein the voltage of the extractor voltage supply is adjusted such that a temperature of a tip of an emitter is adjusted.

51. The non-transitory computer readable medium of any one of clauses 41-50, wherein the voltage of the extractor voltage supply is adjusted such that an electric field of the extractor is adjusted.

52. The non-transitory computer readable medium of any one of clauses 41-51, wherein the set of instructions that is executable by the at least one processor of the computing device to cause the computing device to further perform adjusting the voltage of the extractor voltage supply by transmitting the feedback signal to the extractor voltage supply.

53. The non-transitory computer readable medium of any one of clauses 41-52, wherein the set of instructions that is executable by the at least one processor of the computing device to cause the computing device to further perform adjusting a focus of the emitted beam in response to the adjusted voltage of the extractor voltage supply.

54. The system of any one of clauses 1-14, wherein the emitted beam comprises a portion of an emitted beam.

55. The system of any one of clauses 1-14 or 54, wherein the environment is configured to support a vacuum pressure of less than 1×10⁻¹⁰ torr.

56. The system of clause 15, wherein the emitted beam comprises a portion of an emitted beam.

57. The system of any one of clauses 15 or 56, wherein the environment is configured to support a vacuum pressure of less than 1×10⁻¹⁰ torr.

58. The system of any one of clauses 16-27, wherein the first anode aperture is positioned in an environment that is configured to support a vacuum pressure of less than 3×10⁻¹⁰ torr.

59. The system of any one of clauses 16-27 or 58, wherein the environment is configured to support a vacuum pressure of less than 1×10⁻¹⁰ torr.

60. The method of any one of clauses 28-40, wherein the emitted beam comprises a portion of an emitted beam.

61. The method of any one of clauses 28-40 or 60, wherein the environment is configured to support a vacuum pressure of less than 1×10⁻¹⁰ torr.

62. The non-transitory computer readable medium of any one of clauses 41-53, wherein the emitted beam comprises a portion of an emitted beam.

63. The non-transitory computer readable medium of any one of clauses 41-53 or 62, wherein the environment is configured to support a vacuum pressure of less than 1×10⁻¹⁰ torr.

It will be appreciated that the embodiments of the present disclosure are not limited to the exact construction that has been described above and illustrated in the accompanying drawings, and that various modifications and changes may be made without departing from the scope thereof.

1. An electron beam system comprising:
a first anode aperture configured to measure a current of an emitted beam during inspection of a sample, wherein the first anode aperture is positioned in an environment that is configured to support a vacuum pressure of less than 3×10⁻¹⁰ torr; and
a controller including circuitry configured to cause the system to perform:
generating a feedback signal when a difference between the measured current and a setpoint current exceeds a threshold value; and
adjusting a voltage of an extractor voltage supply based on the feedback signal during inspection of the sample such that a difference between an adjusted current of the emitted beam and the setpoint current is below the threshold value.

2. The system of claim 1, wherein the first anode aperture is configured to measure the emitted beam without perturbing the beam.

3. The system of claim 1, wherein the feedback signal is generated using a proportional-integral-derivative (PID) controller.

4. The system of claim 1, further comprising a second anode aperture configured to accelerate the emitted beam.

5. The system of claim 4, wherein the first anode aperture and the second anode aperture are configured to be isolated from other components of the system.

6. The system of claim 1, wherein the first anode aperture comprises a plurality of segments and each segment of the plurality of segments is insulated from each other.

7. The system of claim 6, wherein each segment of the plurality of segments is configured to measure a current of the emitted beam in during inspection of the sample.

8. The system of claim 7, wherein the circuitry is further configured to cause the system to determine an error based on the current of the emitted beam measured on each segment of the plurality of segments.

9. The system of claim 8, wherein the error comprises an emitter pointing error.

10. The system of claim 8, wherein the error comprises an angular beam emission distribution error.

11. The system of claim 1, wherein the voltage of the extractor voltage supply is adjusted such that a temperature of a tip of an emitter is adjusted.

12. The system of claim 1, wherein the voltage of the extractor voltage supply is adjusted such that an electric field of the extractor is adjusted.

13. The system of claim 1, wherein adjusting the voltage of the extractor voltage supply comprises transmitting the feedback signal to the extractor voltage supply.

14. The system of claim 1, further comprising adjusting a focus of the emitted beam in response to the adjusted voltage of the extractor voltage supply.

15. A non-transitory computer readable medium that stores a set of instructions that is executable by at least one processor of a computing device to cause the computing device to perform a method comprising:
acquiring a measured current of an emitted beam during inspection of a sample, wherein the measured current is measured by a first anode aperture in an environment that is configured to support a vacuum pressure of less than 3×10⁻¹⁰ torr;
generating a feedback signal when a difference between the measured current and a setpoint current exceeds a threshold value; and
adjusting a voltage of an extractor voltage supply based on the feedback signal during inspection of the sample such that a difference between an adjusted current of the emitted beam and the setpoint current is below the threshold value.

16. The non-transitory computer readable medium of claim 15, wherein the first anode aperture is configured to measure the emitted beam without perturbing the beam.

17. The non-transitory computer readable medium of claim 15, wherein the feedback signal is generated using a proportional-integral-derivative (PID) controller.

18. The non-transitory computer readable medium of claim 15, wherein the first anode aperture and a second anode aperture are configured to be isolated from other components of a system, wherein the second anode aperture is configured to accelerate the emitted beam.

19. The non-transitory computer readable medium of claim 15, wherein the first anode aperture comprises a plurality of segments and each segment of the plurality of segments is insulated from each other.

20. The non-transitory computer readable medium of claim 19, wherein each segment of the plurality of segments is configured to measure a current of the emitted beam during inspection of the sample.
